(19) United States
(12) Patent Application Publication
(10) Pub. No.: US 2007/0126346 A1
(43) Pub. Date: Jun. 7, 2007

(54) Dual emission display

(75) Inventors: Min-Chieh Hu, Tainan Hsien (TW); Chun-Yi Chiu, Taoyuan City (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/478,664

(22) Filed: Jul. 3, 2006

(30) Foreign Application Priority Data
Dec. 2, 2005 (TW) 94142594

(51) Int. Cl. H01L 51/00

(52) U.S. Cl. 313/504

(57) ABSTRACT

A dual emission display includes a first substrate whose upper surface has a first organic light emitting diode, a second substrate whose lower surface has a second organic light emitting diode, and the second substrate is on the first substrate. A stress buffer layer fills the gap between the first substrate and the second substrate, and is used to package the first organic light emitting diode to the first substrate and to package the second organic light emitting diode to the second substrate.

This application claims the benefit of Taiwan Patent Application Serial No. 094142594, filed Dec. 2, 2005, the subject matter of which is incorporated herein by reference.

### BACKGROUND OF THE INVENTION

1. Field of the Invention

The present invention relates to a dual emission display having a stress buffer layer.

2. Description of the Prior Art

As the electric products are getting more and more various, they emphasize the structure of two display screens. For example, a mobile phone having a dual emission display can display a main function menu at one side, and display time at the other side. Typically, the dual emission display includes two adhered single-side panels, such as a liquid crystal panel adhered to an organic electro-luminescent panel, two adhered liquid crystal panels, or two adhered organic electro-luminescent panels.

FIG. 1 shows a dual emission display according to the prior art. The dual emission display 10 includes a first display panel 11 and a second display panel 12. The first display panel 11 has a transparent substrate 111, a first electrode 112, an light emitting layer 113, a second electrode 114 and a package lid 115. The first electrode 112 is formed on the transparent substrate 111. The light emitting layer 113 is disposed between the first electrode 112 and the second electrode 114. The package lid 115 is adhered on the transparent panel 111 and covers on the second electrode 114.

The second display panel 12 has a transparent substrate 121, a third electrode 122, an light emitting layer 123, a forth electrode 124 and a package lid 125. The third electrode 122 is formed on the transparent panel 121. The light emitting layer 123 is disposed between the third electrode 122 and the forth electrode 124. The package lid 125 is adhered on the transparent substrate 121. The package lid 115 is adhered to the package lid 125 to construct the dual emission display 10.

As stated above, the typical dual emission display 10 has two package lids 115 and 125, and two transparent substrates 111 and 121. Therefore, it becomes larger, thicker, and heavier. When applying in middle or large-size displays, the substrate is bended easily by forces or gravity. The result is that the light emitting layer or the electrode is possible to peel off.

### SUMMARY OF THE INVENTION

The object of the present invention is to provide a dual emission display filled with a stress buffer layer to protect its organic light emitting diode from peeling off or breaking, or to prevent moisture or oxygen invading.

The dual emission display includes a first substrate whose upper surface has a first organic light emitting diode, a second substrate whose lower surface has a second organic light emitting diode. The second substrate is on the first substrate. A stress buffer layer fills the gap between the first substrate and the second substrate, and is used to package the first organic light emitting diode to the first substrate and to package the second organic light emitting diode to the second substrate.

The stress buffer layer can be made of solid, liquid or colloid anti-stress materials. The organic light emitting diode is fixed on the surface of the substrate by the stress buffer layer. The moisture or oxygen resistance can be enhanced by using the stress buffer layer which features in absorbing moisture or oxygen, or isolating moisture or oxygen, or by adding with the moisture-absorbing or oxygen-absorbing materials in the stress buffer layer.

### BRIEF DESCRIPTION OF THE DRAWINGS

The present invention will now be specified with reference to its preferred embodiment illustrated in the drawings, in which

FIG. 1 is an dual emission display according to the prior art;

FIG. 2 is an first embodiment of the dual emission display according to the present invention; and

FIG. 3 is the second embodiment of the dual emission display according to the present invention.

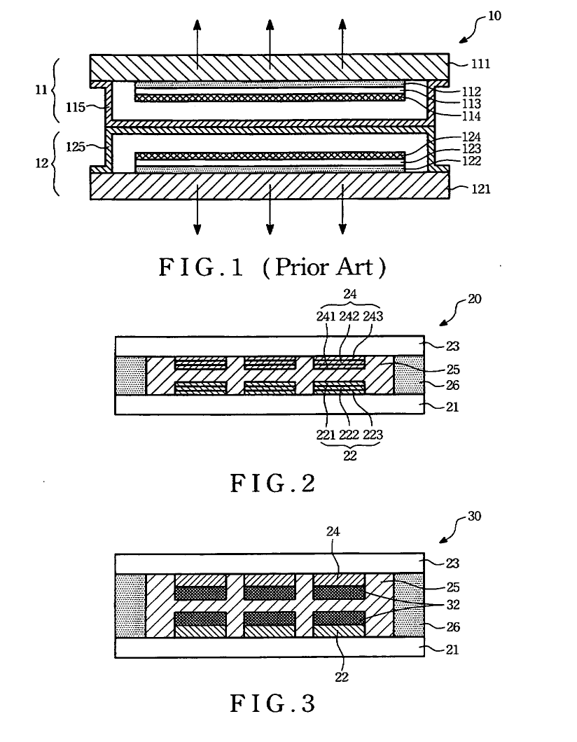

### DESCRIPTION OF THE PREFERRED EMBODIMENT

FIG. 2 shows the first embodiment of the present invention. The dual emission display 20 including a lower substrate 21 adhered to a upper substrate 23 with an adhesive 26. An organic light emitting diode 22 is disposed on the upper surface of the lower substrate 21. Another organic light emitting diode 24 is disposed on the lower surface of the upper substrate 23. A stress buffer layer is filled the gap between the upper and lower substrates 23, 21 to package the organic light emitting diode 22 to the lower substrate 21, and package the organic light emitting diode 24 to the upper substrate 23.

The stress buffer layer 25, which may be solid, liquid or collide, is used to fix the organic light emitting diode 22, 24 to the surface of the substrate 21, 23. It can also prevent external forces from bending the substrates 21 and 23, so as to protect each layer of the organic light emitting diodes 22 and 24 from peeling off or breaking. The moisture or oxygen resistance can be enhanced by using the stress buffer layer which features in absorbing moisture or oxygen, or isolating moisture or oxygen, or by adding with the moisture-absorbing or oxygen-absorbing materials in the stress buffer layer.

FIG. 3 shows the second embodiment of the present invention. The dual emission display 30 includes a protecting layer 32 such as silicon oxide layer, disposed on the surface of the organic light emitting diodes 22 and 24 to enhance the moisture or oxygen resistance.

As mentioned, the organic light emitting diode 22 has a transparent electrode 223, a light emitting layer 222 and a reflective electrode 221. The transparent electrode 223 is closer to the substrate 21 than the reflective electrode 221, so the light can exit from the substrate 21. Likewise, the organic light emitting diode 24 has a reflective electrode 241, a light emitting layer 242 and a transparent electrode 243. The transparent electrode 243 is closer to the substrate 23 than the reflective electrode 241, so the light can exit from the substrate 23. The reflective electrodes 221 and 241 are metal electrodes. By the way, the reflective electrodes 221 and 241 are covered with a deep color or black insulating layer or replaced with a black electrode, or added with anti-reflective or light-absorbing materials for improving the anti-reflective ability and avoiding the leakage of light.

A hole or electron passing area is between the electrodes and the light emitting layer. In the hole passing area, a hole injecting layer (not shown) or a hole transporting layer (not shown) is interposed selectively. In the electron passing area, an electron injecting layer (not shown) or an electron transporting layer (not shown) is interposed selectively.

The electron transporting layer may be made of (8-hydroxyquinolinolato) aluminum (Alq), 1,3,5-Tris (N-phenylbenzimidazol-2-yl)benzene(TPBI), derivatives of anthracene, or derivatives of fluorine, spirofluorine etc., mixed with n-type dopant such as alkali halides, alkaline-earth halides, alkali oxides or metal-carbonate compound etc. to increase electron mobility thereof.

The electron injecting layer may be made of metal compound with work function perfectly adapted to that of the non-transparent electrode, such as alkali halides, alkaline-earth halides, alkali oxides or metal-carbonate compound, or an organic layer mixed with such n-type dopants.

The hole transporting layer may be made of allylamine group material such as N,N-di(naphthalene-1-yl)-N,N-diphenyl-benzidene (NPB).

The hole injecting layer may be made of allylamine group material, or phthalocyanine group material such as CuP.

The fabricating method of the dual emission display 30 is described as follows. The transparent electrode 223 is formed on the lower substrate 21. Organic layers, such as hole injecting layer, the hole transporting layer, the light emitting layer 222, the electron transporting layer and the electrode injecting layer, are formed in order on the transparent electrode 223. Subsequently, the reflective electrode 221 is formed on the organic layers to construct the organic light emitting diode 22. The protecting layer 32 is formed on the reflective electrode 221. The same process is employed on the substrate 23 to fabricate the organic light emitting diode 24 and the protecting layer 32.

A stress buffer material is provided on the surface of the substrate 21 or 23 by screen printing, evaporating, ink-jet printing or one drop filling (ODF). Next the adhesive 26 is coated on the lower or upper substrate 21, 23 and surround the organic light emitting diodes 22 and 24. The stress buffer material may be filled in the region surrounded by the adhesive 26. Finally, the lower substrate 21 is combined with the upper substrate 23, the result is that, the organic light emitting diode 22 corresponds to the organic light emitting diode 24, and the stress buffer material is filled the gap between the substrates 21 and 23 to package the organic light emitting diodes 22 and 24.

The transparent electrode may be made of metal or transparent conductive materials such as ITO, IZO etc.. The transparent substrate may be made of glass or plastic. The dual emission displays described in the present invention may act with the drivers such as thin film transistors, so they can be formed as active or passive displays.

In comparison with the prior art, the present invention has advantages of preferred stress resistant structure, simpler fabricating process and preferred moisture and oxygen resistance.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A dual emission display comprising:
a first substrate;
a first organic light emitting diode disposed on the upper surface of the first substrate;
a second substrate;
a second organic light emitting diode disposed on the lower surface of the second substrate; and
a stress buffer layer filling the gap between the first substrate and the second substrate.

2. The dual emission display of claim 1, wherein the stress buffer layer includes a moisture-absorbing material.

3. The dual emission display of claim 1, wherein the stress buffer layer includes an oxygen-absorbing material.

4. The dual emission display of claim 1, wherein the stress buffer layer is a solid.

5. The dual emission display of claim 1, wherein the stress buffer layer is a liquid.

6. The dual emission display of claim 1, wherein the stress buffer layer is a colloid.

7. The dual emission display of claim 1, further comprising a protecting layer disposed on the surface of the first organic light emitting diode.

8. The dual emission display of claim 7, further comprising a protecting layer disposed on the surface of the second organic light emitting diode.

9. A method for fabricating a dual emission display, comprising:
providing a first substrate;
forming a first organic light emitting diode on the upper surface of the first substrate;
providing a second substrate;
forming a second organic light emitting diode on the surface of the second substrate; and
providing a stress buffer material on the surface of the first substrate and the first organic light emitting diode; and
combining the first and second substrates to oppose the first organic light emitting diode to the second organic light emitting diode; and
filling the stress buffer material in the gap between the first and second substrates, so as to package the first and second organic light emitting diodes.

10. The method of claim 9, wherein providing the stress buffer material includes providing the stress buffer material on the surface of the first substrate by one drop filling.

11. The method of claim 9, wherein providing the stress buffer material includes screen printing the stress buffer material on the surface of the first substrate.

12. The method of claim 9, wherein providing the stress buffer material includes evaporating the stress buffer material on the surface of the first substrate.

13. The method of claim 9, wherein providing the stress buffer material includes ink-jet printing the stress buffer material on the surface of the first substrate.

14. The method of claim 9, further comprising:
coating an adhesive on the first and second substrates, so that the adhesive surrounds the first and second organic light emitting diodes; and
filling the stress buffer material in the region surrounded by the adhesive.

15. The method of claim 9, further comprising forming a protecting layer on the surface of the first organic light emitting diode.

16. The method of claim 9, further comprising forming a protecting layer on the surface of the second organic light emitting diode.
